(19) United States
(12) Patent Application Publication
(10) Pub. No.: US 2025/0208172 A1
(43) Pub. Date: Jun. 26, 2025

(54) MODULE FOR ESTIMATING VOLTAGE

(71) Applicant: Alberto BAUER, Al Menara (AE)

(72) Inventor: Alberto BAUER, Al Menara (AE)

(21) Appl. No.: 18/849,477

(22) PCT Filed: Apr. 13, 2023
(86) PCT No.: PCT/IT2023/000007

§ 371 Date: Sep. 21, 2024

(30) Foreign Application Priority Data
Apr. 15, 2022 (IT) 102022000007415

(51) Int. Cl. G01R 15/16; G01R 19/00

(52) U.S. Cl. CPC G01R 15/16; G01R 19/0084

(57) ABSTRACT

A Module (MA) for a system (100.S/200.S) suitable for estimating the value of the electric voltage comprises at least a first capacitor (C1.sx) and a second capacitor (C1.dx. The first capacitor (C1. left) comprises a first pole (C1.sx.p1) and a second pole (C1.sx.p2). The second capacitor (C1.dx) includes a first pole (C1.dx.p1) and a second pole (C1.dx.p2). The first capacitor (C1.sx) has its first pole (C1.sx.p1) connected to said live element (ET) and the second capacitor (C1.dx) has its first pole (C1.dx.p1) connected to said live element (ET).

### FIELD OF INVENTION

The present invention concerns the sector of modules relating to systems for estimating the value of the electrical voltage of a live element.

More particularly, the present invention relates to a module of the aforementioned type, particularly suitable for estimating the value of the electric voltage of a conductor, or of a bar, or of a bushing, or of another live element positioned anywhere.

### BACKGROUND OF THE INVENTION

Modules relating to systems are currently known for estimating the value of the electrical voltage of a live element, but said modules and related systems have a series of drawbacks.

A first drawback is due to the fact that they do not allow a correct and/or safe estimate of the electrical voltage value of the live element to be maintained over time, due to the aging of the electrical components and/or due to other reasons.

A second drawback is due to the fact that they require maintenance which is difficult and costly in order to maintain a desired measurement precision over time.

A third drawback is due to the fact that they do not allow maintenance and/or repair operations to be carried out on the system if the element being measured is live.

A fourth drawback is due to the fact that highly skilled workers only must be used to carry out the maintenance and/or repair of said systems.

### OBJECT OF THE INVENTION

The object of the present invention is therefore to solve the aforementioned drawbacks.

The invention, which is characterized by the claims, solves the problem of creating a module for a system suitable for estimating the value of the electric voltage relating to a live element, in which said module, defined here as the first module, is characterized by the fact to comprise at least a first capacitor and a second capacitor; wherein said first capacitor comprises a respective first pole and a second pole; wherein said second capacitor comprises a respective first pole and a second pole; wherein said first capacitor has its first pole connected to said live element; wherein said second capacitor has its first pole connected to said live element.

### BRIEF DESCRIPTION OF THE DRAWINGS

Further characteristics and advantages of the present invention will be more evident from the following description of some of its preferred practical embodiments, given here by way of purely non-limiting example, made with reference to the figures of the attached drawings in which:

FIG. 1 schematically illustrates the module object of the present invention applied to a first exemplary embodiment of a first system;

FIG. 2 schematically illustrates the module object of the present invention applied to a second exemplary embodiment of a second system;

FIGS. 3 and 4 illustrate waveforms of electrical voltage.

### PREFERRED EXAMPLE FORMS OF PRACTICAL EMBODIMENTS

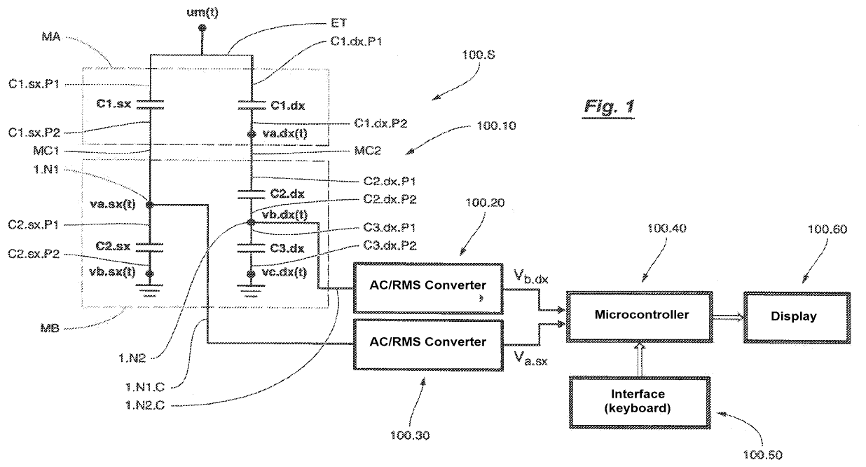

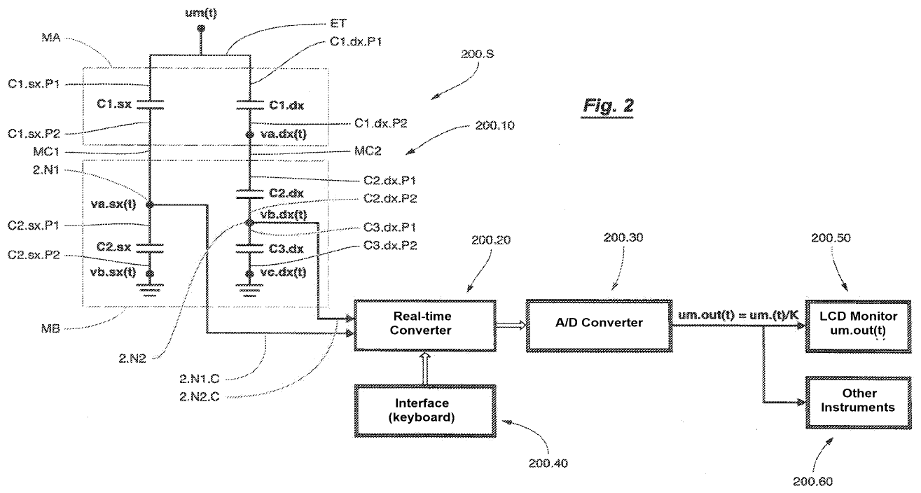

With reference to FIGS. 1 and 2, the present invention relates to a module MA particularly suitable for a system suitable for estimating the value of the electric voltage relating to a live element ET, such as for example for a system 100.S/200.S described below, wherein said module MA, defined herein as first module MA, substantially comprises at least a first capacitor C1.sx and a second capacitor C1.dx, wherein the first capacitor C1.sx comprises a first pole C1.sx.p1 and a second pole C1.sx.p2, wherein the second capacitor C1.dx comprises a first pole C1.dx.p1 and a second pole C1.dx.p2, wherein the first capacitor C1.sx has its first pole C1.sx.p1 connected to said live element ET, and wherein the second capacitor C1.dx has its first pole C1.dx.p1 connected to said live element ET.

With reference to this first module MA, according to a preferred embodiment, the first capacitor C1.sx and the second capacitor C1.dx are two equal and/or identical capacitors.

Again with reference to this first module MA, preferably, the first capacitor C1.sx and the second capacitor C1.dx are two capacitors having a respective dielectric identical to each other and/or a respective dielectric not identical (different) to each other but having the same characteristics in relation to the change of these characteristics if these two capacitors will be subjected, over time, to the same vicissitudes.

Always with reference to this first MA module, the first capacitor C1.sx and the second capacitor C1.dx can be two capacitors (two capacities) with a known ratio in relation to the values of the respective capacities, i.e. two capacitors C1.sx and C1.dx which will have a respective capacitance value, Vdc_C1.sx and Vdc_C1.dx, where these two values have a ratio, . . . C1.sx/C1.dx=known_r_value . . . , then consider said known_r_value in the equation/calculation for estimating the voltage relating to the live element ET.

Still preferably, said first capacitor C1.sx and said second capacitor C1.dx are connected to the live element ET and/or positioned and/or placed and/or arranged inside said first module MA, in such a way to be subjected, during the passage of time, for example after their installation, to the same operating, working, environmental, aging conditions, such as, for example, fixed to the same conductor ET supported on the top of a pylon and, therefore, both subjected to the same weather conditions that will occur with the passage of time.

Always if desirable, the first module MA can be connected by means of connection means MC1 and MC2 to a second module MB, in which the latter can be able for conditioning the signals received from said first module MA, in which said second module MB is separate but connectable with respect to said first module MA, in order to be able to position said second module MB separately with respect to said first module MA, preferably selecting for this second module MB a positioning in a more accessible and/or sheltered place, as for example into an electrical substation.

According to a preferred embodiment, the second module MB can comprise: a third capacitor C2.sx comprising a respective first pole C2.sx.p1 and a second pole C2.sx.p2; a fourth capacitor C2.dx comprising a respective first pole C2.dx.p1 and a second pole C2.dx.p2; and a fifth capacitor C3.dx comprising a respective first pole C3.dx.p1 and a second pole C3.dx.p2.

In this preferred embodiment in the second module MB, schematically and substantially: the third capacitor C2.sx has its first pole, C2.sx.p1, are connected by means of first connection means, MC1, to the second pole C1.sx.p2 of the first capacitor C1.sx, and its second pole, C2.sx.p2, connected to the ground; the fourth capacitor, C2.dx, has its first pole, C2.dx.p1, connected by means of second connection means MC2 to the second pole, C1.dx.p2, of the second capacitor C1.dx, and its second pole, C2.dx.p2, connected to the first pole, C3.dx.p1, of the fifth capacitor C3.dx; the fifth capacitor, C3.dx, has its second pole, C3.dx.p2, connected to ground.

With reference to FIG. 1, which illustrates a first exemplifying form of a system S.100 in which said first module MA is applied, the second module MB, as described above, comprises a third capacitor C2.sx, a fourth capacitor C2. dx and a fifth capacitor C3.dx and, furthermore, always said second module MB, can be connected to a group of first further components, better described hereinafter, which can be included in the second module MB or arranged separately with respect to said second MB module.

More particularly, these second further components may comprise: a first AC/RMS converter 100.20 connected via a respective conductor 1.N2.C to a node 1.N2 positioned along the connection conductor between the fourth capacitor C2.dx and the fifth capacitor C3.dx; a second AC/RMS converter 100.30 connected by means of a respective conductor 1.N1.C to a first node 1.N1 positioned along the connecting conductor between the first capacitor C1.sx and the third capacitor C2.sx; a microcontroller 100.40 connected to said first and second converters 100.20 and 100.30; a user interface (keyboard) 100.50 connected to said microcontroller 100.40 for data entry, such as for example entry of the capacitance values of the capacitors; a display 100.60 connected to said microcontroller 100.40.

With reference to FIG. 2, which illustrates a second exemplary form of a system S.200 in which said first module MA is applied, the second module MB, as described above, comprises a third capacitor C2.sx, a fourth capacitor C2. dx and a fifth capacitor C3.dx and, furthermore, always said second module MB, can be connected to a group of second further components, which can be included in the second module MB or arranged separate from said second module MB.

More particularly, these second additional components may comprise: a Real-Time Microcontroller 200.20, connected via a respective conductor, 2.N2.C, to the second node 2.N2 positioned along the connection conductor between the fourth capacitor C2.dx and the fifth capacitor C3.dx, and connected by means of a conductor, 2.N1.C, to the first node 2.N1 positioned along the connecting conductor between the first capacitor C1.sx and the third capacitor C2.sx; a Digital-Analog Converter 200.30 connected to said Real_Time Microcontroller 200.20; a user interface (keyboard) 200.40 connected to said Real_Time Microcontroller 200.20 for entering data, such as for example for entering data relating to the transformation ratio “k”; an LCD monitor 200.50 connected to said Converter 200.30; other instruments 200.60.

By means of the first module MA as applied in the system 100.S/200.S described above, the estimate of the value of the electrical voltage of the element under voltage ET can be calculated in different ways using the following values: 1) at least a voltage value pertaining to the first point/node 1.N1/2.N1 positioned along the conducting wire C1.sx.P2_MC1_C2.sx.p1 which connects the first capacitor C1.sx to the third capacitor C2.sx; 2) at least a voltage value relating to the second point/node 1.N2/2.N2 positioned along the conducting wire C2.dx.p2_C3.dx.p1 which connects the fourth capacitor C2.dx to the fifth capacitor C3.dx; 3) at least a capacitance value of the third capacitor C2.sx; 4) at least a capacitance value of the fourth capacitor C2.dx; 5) at least a capacitance value of the fifth capacitor C3.dx.

According to a first exemplary embodiment object of the present invention, see FIG. 1, by means of the module MA as applied in the system 100.S, the voltage value of the element ET is calculated by means of the following equation

$$… um = \frac{\begin{matrix}Va . sx . Vb . dx . \\ ( C 2. sx . C 3. dx + C 2. sx . C 2. dx - C 2. dx . C 3. dx )\end{matrix}}{C 2. dx . ( Va . sx . C 2. sx - Vb . dx . C 3. dx )} \qquad ( equation\_ 1 )$$

where
Um=RMS value of the voltage relating to said element under voltage ET
Va.sx=Effective value of the voltage relating to the second pole C1.sx.p2 of the first capacitor C1.sx and/or relating to a first node 1.N1 positioned along the conducting wire C1.sx.P2_MC1_C2.sx.p1 which connects the first capacitor C1.sx to third capacitor C2.sx;
Vb.dx=Effective value of the voltage relating to the second pole C2.dx.p2 of the fourth capacitor C2.dx and/or relating to a second node 1.N2 positioned along the conducting wire C2.dx.p2_C3.dx.p1 which connects the fourth capacitor C2.dx to fifth capacitor C3.dx;
C2.sx=Capacitance value of the third capacitor C2.sx;
C2.dx=Capacitance value of the fourth capacitor C2.dx;
C3.dx=Capacitance value of the fifth capacitor C3.dx

According to a second exemplary embodiment object of the present invention, see FIG. 2, by means of the module MA as applied in the system 200.S, the voltage value of the element ET is calculated by means of the following equation

$$um ( t ) = \frac{\begin{matrix}va . sx ( t ) . vb . dx ( t ) . \\ ( C 2. sx . C 3. dx + C 2 sx . C 2. dx - C 2. dx . C 3. dx )\end{matrix}}{C 2. dx . ( va . sx ( t ) . C 2. sx - vb . dx ( t ) . C 2. dx )} \qquad ( equation\_ 2 )$$

where
um(t)=Estimated value of the instantaneous primary voltage relating to said element under voltage ET
va.sx(t)=Value of the instantaneous voltage relating to the second pole C1.sx.p2 of the first capacitor C1.sx and/or relating to a first node 2.N1 positioned along the conducting wire C1.sx.P2_MC1_C2.sx.p1 which connects the first capacitor C1.sx to the third capacitor C2.sx;
vb.dx(t)=Value of the instantaneous voltage relating to the second pole C2.dx.p2 of the fourth capacitor C2.dx) and/or relating to a second node 2.N2 positioned along the conducting wire C2.dx.p2_C3.dx.p1 which connects the fourth capacitor C2.dx to the fifth capacitor C3.dx;
C2.sx=Capacitance value of the third capacitor C2.sx;
C3.dx=Capacitance value of the fifth capacitor C3.dx
C2.dx=Capacitance value of the fourth capacitor C2.dx.

### Components

With reference to the first and second embodiments, 100.S/200.S, illustrated in the respective FIGS. 1 and 2, as an example of non-limiting embodiment, the system described above could comprise:
as first capacitor C1.sx, a capacitor made by Vishay company, product no. 715C30KTT33, having the following characteristics: ceramic capacitor, capacity: 330 pF, ac rated voltage: 20 kV;
as second capacitor C1.dx, a capacitor manufactured by Vishay company, product no. 715C30KTT33 having the following characteristics: ceramic capacitor, capacity: 330 pF, ac rated voltage: 20 kV;
as third capacitor C2.sx, a capacitor manufactured by Kemet company, product no. Type C1002_X7R, having the following characteristics; ceramic capacitor, capacity: 590 nF, rated voltage 100V, NP0;
as fourth capacitor C2.dx, a capacitor manufactured by Kemet company, product no. Type C1002_X7R, having the following characteristics; ceramic capacitor, capacitance: 20 pF, rated voltage: 50V, NP0;
as fifth capacitor C3.dx, a capacitor manufactured by Kemet company, product no. C1812C683J1 GACAUTO, having the following characteristics: ceramic capacitor, capacity: 630 nF, rated voltage: 100V, NP0, ceramic.

In this context, it is specified that the devices C1.sx, C1.dx, C2.sx, C2.dx and C3.dx specified above, by way of example, can also assume other embodiments, suitable for performing the same function, without departing from the inventive concepts protected by the present invention.

With particular reference to the first embodiment, illustrated in FIG. 1, system 100.S, as an example of non-limiting embodiment, the system described above could comprise: as the first ac/rms value converter 100.20, a device capable of converting an alternating voltage waveform into a direct voltage, i.e. capable of calculating (converting) the effective value of an alternating quantity which reaches the input of said first converter device 100.20, such as for example a commercial converter device known as model AD736 produced by the company Analog Devices; as second AC/RMS converter 100.30, an identical and/or analogous converter device with respect to the previous first converter 100.20; as microcontroller 100.40, a device suitable for calculating mathematical formulas, in which said microcontroller 100.40 is always preferably provided with an analog-digital converter for acquiring instantaneous signals, converting them into digital numbers, performing the operations and, therefore, communicating the results to an external display, such as for example a commercial microcontroller known as model PIC24FJ128GC006 manufactured by Microchip Technologies Inc.; as display 100.50, a device for presenting information, preferably a liquid crystal display of the 4-line type with 20 characters per line, such as for example a commercial display LCD-20x4Y produced by the company Gravitech; as a user interface (keyboard) 100.60, a keyboard or other similar device capable of allowing data and/or commands to be entered into the aforementioned Microcontroller 100.40.

In this context, it is specified that the devices 100.20, 100.30, 100.40, 100.50 and 100.60, specified above by way of example, can also assume other embodiments, capable of performing the same functions, without departing from the inventive concepts protected by the present invention.

With particular reference to the second embodiment, illustrated in FIG. 2, as an example of non-limiting embodiment, the system 200.S described above could comprise: as a Real-Time Microcontroller 200.20, a device suitable for calculating formulas and the modification of acquired signals with an internal analog-digital converter, also having characteristics that allow it to operate with real-time operating systems, such as, for example, a Real-Time microcontroller known as the DSPIC33FJ16GS402_H/MM model produced by company Microchip Technologies Inc.; as Digital-Analog Converter 200.30, a Digital-Analog converter device suitable for converting a series of data in digital format into an instantaneous-analog signal, such as, for example, a commercial Digital-Analog Converter known as model DAC121S101CIMM/NOPB manufactured by the company Texas Instruments; as user interface (keyboard) 200.40, a keyboard or other similar device able to allow data and/or commands to be entered into the aforementioned microcontroller 200.20.

In this context, it is specified that the devices 200.20, 200.30, 200.40, specified above by way of example, can also assume other embodiments, suitable for performing the same functions, without departing from the inventive concepts protected by the present invention.

### First Example of Calculation—System 100.S of FIG. 1

As an example, with reference to the first module MA and to the system 100.S of FIG. 1, using the components as indicated above and substantially
a first capacitor C1.sx having capacity: 330 pF;
a second capacitor C1.dx having capacity: 330 pF;
a third capacitor C2.sx having a capacity of 590 nF;
a fourth capacitor C2.dx having capacity: 20 pF;
a fifth capacitor C3.dx having capacity: 630 nF,
   by applying the system 100.S to an element ET having voltage, the following values were detected
at the output of the second converter 100.30 a Va.sx value=0.25312 V
at the output of the first converter 100.20 a value Vb.dx=0.13554 V
   and, on the basis of the aforementioned equation, i.e.

$$… um = \frac{\begin{matrix}Va . sx . Vb . dx . \\ ( C 2. sx . C 3. dx + C 2. sx . C 2. dx - C 2. dx . C 3. dx )\end{matrix}}{C 2. dx . ( Va . sx . C 2. sx - Vb . dx . C 3. dx )} \qquad ( equation\_ 1 )$$

we will have as a calculation performed by the Microcontroller 100.40

Um=0.25312 V·0.13554 V·(590 nF·630 nF+590 nF·20 pF−20 pF·630 nF)/(20 pF·(0.25312 V·590 nF−0.13554 V·630 nF))

whose result corresponds to

Um=9.970.2 V

### Second Calculation Example—System 200.S of FIG. 2

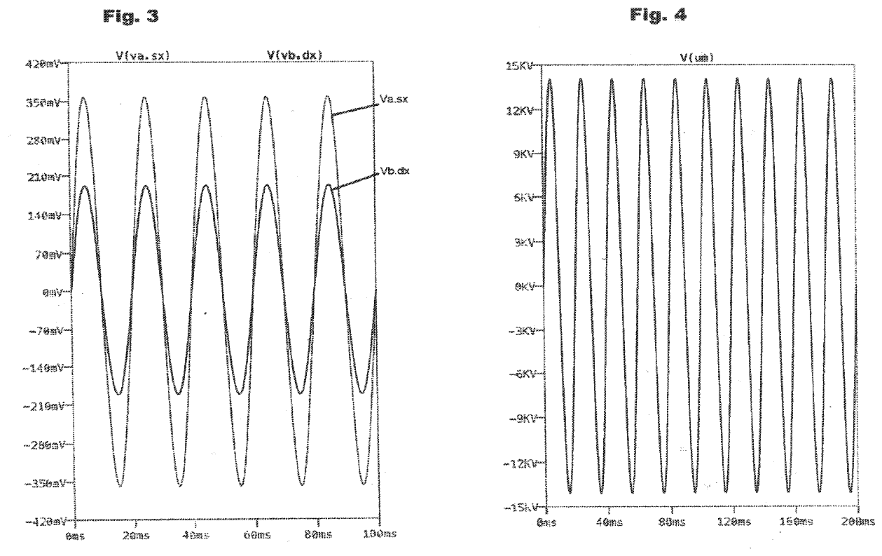

Also by way of example, with reference to the first module MA and to the system 200.S of FIG. 2, using the components as indicated above, by applying the system 200.S to an element ET having voltage, the waveforms illustrated were detected in FIG. 3. The Real Time micro-controller divides the instantaneous voltages va.sx(t) and vb.dx(t) by the transformation ratio k, previously entered using the keyboard 200.40 or other system and using the equation

$$um ( t ) = \frac{\begin{matrix}va . sx ( t ) . vb . dx ( t ) . \\ ( C 2. sx . C 3. dx + C 2 sx . C 2. dx - C 2. dx . C 3. dx )\end{matrix}}{C 2. dx . ( va . sx ( t ) . C 2. sx - vb . dx ( t ) . C 2. dx )} \qquad ( equation\_ 2 )$$

where the result obtained was the waveform illustrated in FIG. 4.

With reference to the above description, the term “module” MA is preferably used to define an independent unit of a complex comprising, for example, two or more modules MA MB that can be connected together and/or two or more independent units MA MB, which are connectable each other, for example by means of conductors, and/or an independent unit MA and other components connectable to said unit MA by means of conductors such as, for example

$$> \_MA + MB + 100.2 + 100.3 + 100.4 + 100.5 + 100.6 \qquad ( fig . 1 )$$

$$> \_MA + MB + 200.2 + 200.3 + 200.4 + 200.5 + 200.6 \qquad ( fig . 2 )$$

Still preferably, said module MA comprises specific and particular components and, furthermore, is intended to perform a particular and specific function as part of an apparatus and/or a circuit and/or a complex and/or a system.

Always preferably, said module MA is made as an autonomous self-supporting unit, so that it can be easily removed and/or replaced and/or disconnected with respect to the respective apparatus and/or circuit and/or complex and/or system and, if desirable, said module MA can also provide a shield to protect the related components from the surrounding electric fields.

By means of the module object of the present invention a correct and/or safe estimate of the voltage value of the live element is maintained over time, solving the problems above mentioned.

By means of the module object of the present invention and the related system, a correct and/or safe estimate of the voltage value of the live element is maintained over time, simple and inexpensive maintenance can be performed since the module MA does not require maintenance and the module MB can be positioned in an easily accessible location (such as for example into an electrical substation) and, therefore, the maintenance and/or repair of said systems, for example in relation to the Module MB, can also be performed if the element subject to measurement is live (for example providing the connection means MC1 and MC2 with disconnectors), the repair and maintenance operations can be carried out, for example of the Module MB, by unskilled workers.

The description of the modules and systems as indicated above is given as a purely non-limiting example and, therefore, it is evident that all those modifications or variations suggested by practice and by their use or employment can be made to said modules and, in any case, within the scope of the following claims, which also form an integrative part for the present description.

1. A system for estimating a voltage of a live element, the system comprising:
a first capacitor having a respective first pole and a second pole; and
a second capacitor having a respective first pole (C1.dx.p1) and a second pole, it's the first pole of the first capacitor and it's the first pole of the second capacitor each being connected to the live element (ET).

2. The module according to claim 1, wherein the first capacitor and the second capacitor are equal or identical.

3. The module according to claim 1, wherein the first capacitor and the second capacitor have respective dielectric materials identical to each other or respective dielectric materials not identical to each other but whose characteristics change or mutate identically if the two not identical dielectric material are subjected over time to the same functional or environmental or aging vicissitudes.

4. The module according to any claim 1, wherein the first capacitor and the second capacitor have a predetermined ratio in relation to the values of the respective capacities.

5. The module according to any claim 1, wherein the first capacitor and the second capacitor are connected to the live element in such a way as to be subjected over the course of time to the same operating or environmental or aging conditions.

6. The module according to claim 1, wherein the first module is connected by a connection to a second module for conditioning the signals received from the first module, and the second module being positioned apart from the first module.

7. The module according to claim 6, wherein the second module has:
a third capacitor having a respective first pole and a respective second pole;
a fourth capacitor having a respective first pole and a respective second pole;
a fifth capacitor having a respective first pole and a second pole;
the third capacitor having its first pole connected by first connection means to the second pole of the first capacitor and by its second pole to ground;
the fourth capacitor having its first pole connected by second connection means to the second pole of the second capacitor and its second pole connected to the first pole of the fifth capacitor;
the fifth capacitor having its second pole connected to ground.

8. The module according to claim 7, wherein the second module MB is connected to a set of further components comprising:
a first AC/RMS converter connected by a respective conductor to a second node positioned along the conductor between the fourth capacitor and the fifth capacitor;
a second AC/RMS converter connected by a respective conductor to a first node positioned along the conductor between the first capacitor and the third capacitor;
a microcontroller connected to the first and second converter.

9. The module according to claim 7, wherein the voltage of the live element is calculated using the following equation:
$$Um = \frac{\begin{matrix}Va . sx . Vb . dx . \\ ( C 2. sx . C 3. dx + C 2. sx . C 2. dx - C 2. dx . C 3. dx )\end{matrix}}{C 2. dx . ( Va . sx . C 2. sx - Vb . dx . C 3. dx )}$$
where
Um=effective value of the voltage of the live element ET;
Va.sx=effective value of the voltage regarding the second pole of the first capacitor or regarding a first node positioned along the conductor connecting the first capacitor to the third capacitor;
Vb.dx=effective value of the voltage regarding the second pole of the fourth capacitor or regarding a second node positioned along the conductor connecting the fourth capacitor to the fifth capacitor;
C2.sx=electric capacity value of the third capacitor;
C2.dx=electric capacity value of the fourth capacitor;
C3.dx=electric capacity value of the fifth capacitor.

10. The module according to claim 7, wherein the second module is connected to a set of further components comprising:
a Microcontroller Real-Time connected by a respective conductor to a second node positioned along the conductor between the fourth capacitor and the fifth capacitor and connected by a conductor to a first node positioned along the conductor connecting the first capacitor with the third capacitor;
a Digital-Analog Converter connected to the microcontroller.

11. The module according to claim 7, wherein the electrical voltage of the live element is calculated using the following equation:
$$um ( t ) = \frac{\begin{matrix}va . sx ( t ) . vb . dx ( t ) . \\ ( C 2. sx . C 3. dx + C 2 sx . C 2. dx - C 2. dx . C 3. dx )\end{matrix}}{C 2. dx . ( va . sx ( t ) . C 2. sx - vb . dx ( t ) . C 2. dx )}$$
where
um (t)=Estimated value of instantaneous primary voltage of the live element;
va.sx (t)=Value of the instantaneous electric voltage of the second pole of the first capacitor or of a first node positioned along the conductor which connects the first capacitor to the third capacitor;
vb.dx (t)=Value of the instantaneous electric voltage of the second pole of the fourth capacitor or of the a second node positioned along the conductor that connects the fourth capacitor with the fifth capacitor;
C2.sx=electric capacity value of the third capacitor;
C3.dx=electric capacity value of the fifth capacitor.
C2.dx=electric capacity value of the fourth capacitor.

12. The module according to claim 1.
